(19) United States
(12) Patent Application Publication
(10) Pub. No.: US 2010/0000831 A1
(43) Pub. Date: Jan. 7, 2010

(54) Brake and clutch discs

(75) Inventors: Julio Joseph Faria, Cheshire (GB); Kevin Johnson, Lancashire (GB); Geoffrey Gould, Warwickshire (GB)

Correspondence Address: THE FIRM OF HUESCHEN AND SAGE, SEVENTH FLOOR, KALAMAZOO BUILDING, 107 WEST MICHIGAN AVENUE, KALAMAZOO, MI, 49007, US

(73) Assignee: SURFACE TRANSFORMS PLC, Ellesmere Port, Cheshire (GB)

(21) Appl. No.: 11/989,310

(22) PCT Filed: Jul. 28, 2006
(86) PCT No.: PCT/GB2006/002815

§ 371 Date: Sep. 4, 2009

(30) Foreign Application Priority Data
Jul. 29, 2005 (GB) 0515647.6

(51) Int. Cl. F16D 69/02; C23C 16/22

(52) U.S. Cl. 188/251 A; 427/249.2

(57) ABSTRACT

Highly effective carbon fibre-reinforced ceramic automotive brake and clutch discs are manufactured by siliconising incompletely densified carbon-carbon fibre preforms produced by a single stage and relatively short duration (e.g. 7-14 day) chemical vapour infiltration process.

This invention relates to a method for manufacturing brake and clutch discs for motorised land vehicles and to novel brake and clutch discs which are obtainable thereby. More particularly it concerns brake and clutch discs comprising carbon fibre-reinforced ceramic material such as may be obtained by using chemical vapour infiltration to deposit a carbon matrix around the reinforcing carbon fibres and thereafter impregnating the carbon matrix with molten silicon.

Much interest has been shown in the use of carbon fibre-reinforced ceramic brake discs, in particular siliconised carbon-carbon fibre composites, because of their high strength, their ability to maintain excellent physical and frictional properties at high operating temperatures, and their low weight compared to conventional metal discs, for example permitting a weight reduction of 50-60% relative to a standard cast iron disc. Such weight reduction is important in improving performance and fuel economy; by reducing the unsprung weight of a vehicle it may also improve the road holding, handling and comfort of the vehicle. Motor vehicles may likewise benefit from the use of such low weight high friction materials in clutch discs.

Existing commercially available siliconised carbon fibre-reinforced ceramic brake discs are all prepared by a “resin char” method in which the reinforcing carbon fibres and a carbonisable resin (e.g. pitch or a phenolic resin) are hot moulded together to approximately the desired shape, and the resulting moulded preform is carbonised (e.g. by heating to ca. 1000° C. under an inert atmosphere or in vacuo), and optionally graphitised (e.g. by heating to ≧2000° C.). The resulting green bodies may then be shaped and/or joined together as appropriate, and are siliconised, for example by at least partial immersion in a bath of molten silicon or by a hot isostatic pressure treatment involving encapsulation with excess silicon in an evacuated container which is then subjected to high temperature and isostatic pressure.

Resin char procedures have the advantage of being relatively simple to operate, but do suffer a number of disadvantages. Thus the mould is normally filled with randomly oriented short carbon fibres, typically having an average length of less than 30 mm, more commonly less than 25 mm. The fibres may, for example, be chopped from matchstick-like aggregates of carbon fibres which have been preimpregnated with resin; alternatively dry fibres chopped from a carbon fibre fabric such as a felt may be used, in which case resin is separately injected into the mould. It will be appreciated that the random orientation of the short carbon fibres necessarily limits the reproducibility of products obtained using resin char procedures.

Another disadvantage is that the resin tends to shrink away from and expose some of the carbon fibre content during carbonisation. The integrity of such exposed fibres may be damaged by reaction with silicon in the subsequent siliconisation step.

The need to use a mould also puts practical limitations on the procedure, since any desired changes to the shape of the product will necessitate potentially expensive retooling.

It is known in the art that chemical vapour infiltration may be used as an alternative to resin char processing in order to form carbon-carbon fibre composites, although it is generally considered to be unduly complicated and too expensive for more than highly specialised uses such as the manufacture of carbon-carbon fibre composite brake discs for aircraft. The manufacture of such discs typically involves generation of an initial carbon fibre preform which is then subjected to a sequence of chemical vapour infiltration steps, for example using methane as the source of pyrolitic carbon. A sequence of steps is needed because the depositing carbon tends to block the pores between the reinforcing fibres, thereby halting carbon uptake. Initial saturation typically occurs after 10-14 days; by this time the preform may have a density of the order of 1.4-1.5 g/cm³ and will not yet have sufficient strength or integrity for use as a brake disc. It is therefore normal practice to remove the partially densified preform from the furnace and machine its surfaces in order to reopen the blocked pores, whereafter chemical vapour infiltration may be resumed. At least one further machining step and a third chemical vapour infiltration stage are normally required in order to obtain a disc with an acceptable density of around 1.8-1.9 g/cm³; the total processing time is typically of the order of 150 days. U.S. Pat. No. 6,878,331 confirms that chemical vapour infiltration generally has to be repeated three to five times before the desired density is achieved.

Discs obtaining in this way are not siliconised, and function well as aircraft brakes. They are, however, inappropriate for use in land vehicles, since they exhibit poor frictional properties at ambient temperatures and so cannot be used to provide occasional light braking.

It has hitherto been thought that even chemical vapour infiltration-generated discs which are intended to be siliconised require at least two stages of infiltration to be performed. Thus it is noted in U.S. Pat. No. 6,030,913 that if chemical vapour infiltration is used only once per process, then microcracks remain in the deposited pyrocarbon layer and permit unwanted penetration of silicon during siliconisation. It is observed that multistage infiltration to overcome this problem is very costly.

Whilst U.S. Pat. No. 6,110,535 describes a technique for delivering a molten silicon composition into porous substrates of carbon composite material which may be obtained by densification using chemical vapour infiltration, this is normally the first step of a two stage densification process and is followed by a resin char densification so as to form grains of coke in the pores of the residual pore space remaining after the chemical vapour infiltration.

The present invention is based on the unexpected finding that highly effective siliconised carbon-carbon fibre composite brake and clutch discs may in fact be manufactured by siliconisation of incompletely densified preforms which have undergone only a single chemical vapour infiltration densification step. It is therefore possible to reduce the chemical vapour infiltration processing time from around 150 days to as little as, for example, seven days or less, greatly reducing process operating costs and permitting the manufacture of brake and clutch discs with highly advantageous properties at costs comparable to those of procedures using resin char processing. The reduced operating costs make the products commercially viable for application to motorised land vehicles, including both road going and racing cars and motorbikes, as well as vans, lorries, buses and coaches, military vehicles and railway engines, coaches and trucks.

Thus according to one aspect of the invention there is provided a method for the manufacture of a carbon fibre-reinforced ceramic brake or clutch disc for a motorised land vehicle, which method comprises preparing a carbon fibre preform having dimensions which substantially correspond to those of the desired disc, densifying said preform with carbon in a single stage chemical vapour infiltration process, and siliconising said densified preform by reaction with molten silicon.

A major advantage of the process of the invention is that, by avoiding the use of moulds, minimal constraints are placed on the shape of the carbon fibre preform, which may be varied as required without the need for major retooling, thereby rendering the manufacturing process highly versatile.

There are similarly no constrains on the length of the carbon fibres which may be used. The preforms may therefore advantageously consist essentially of long fibres, for example having an average length of at least 50 mm, preferably at least 75, 100, 125 or 150 mm, since long fibres enhance the strength and integrity of the product. Without wishing to be bound by theoretical considerations, it may be that the presence of long fibres is beneficial in ensuring that the products remain free from structural defects such as microcracks in contrast to the single stage chemical vapour infiltration-generated prior art products discussed earlier.

It is particularly preferred that the reinforcing carbon fibres are essentially continuous, i.e. that the average fibre length is equal to or exceeds the radial distance between the inner and outer peripheries of the disc. A particularly simple method of preparing such a continuous fibre preform is to cut it from a continuous sheet or cylinder of carbon fibre fabric, for example a woven fabric or a non-woven felt comprising alternating layers of carbon fibres laid at different angles, e.g. 0° and 90°.

The chemical vapour infiltration step may be conducted in per se known manner in an appropriate furnace, which is preferably highly lagged to ensure that heating costs are kept as low as possible. Low molecular weight hydrocarbons such as methane, propane or butane or mixtures of any of these gases may, for example, be used as pyrolytic carbon source and may, for example, be applied in conjunction with a carrier gas such as nitrogen. For cost reasons use of methane may be preferred. The process may, for example, be operated at a temperature of about 1100° C., e.g. 1100±50° C., for a period of up to 21 days, preferably 7-14 days, during which time the density of the preform will typically increase from an initial 0.3-0.6 g/cm³ to a value in the range 1.0-1.5 g/cm³.

It will be appreciated that the morphology of the carbon matrix laid down during chemical vapour infiltration can be varied by appropriate control of the operating temperature and pressure, in a manner which is not possible when using a resin char process. The reactivity of the matrix may be modified in this way, permitting “fine tuning” of the relative carbon, silicon and silicon carbide contents of the siliconised matrix in order to optimise the structural and frictional properties of the end product.

If desired the partially densified preform may be graphitised prior to siliconisation, for example by heat treatment at ca. 2000° C. or above, e.g. up to 2400° C., under non-oxidising conditions, e.g. under an inert gas such as argon or in vacuo, for example for a period of about 96 hours at peak temperature.

Siliconisation may be effected in any appropriate manner such as is known in the art. For ease of operability a dip process in which the optionally graphitised partially densified preform is at least partially immersed in a bath of molten silicon or a hot isostatic pressing procedure may be preferred.

The product may be machined to its desired final dimensions either before or after siliconisation. The former option may be preferred since the presiliconisation intermediate product is less hard and therefore more readily machinable than the siliconised end product.

Carbon fibre-reinforced ceramic brake and clutch discs obtainable in accordance with the method of the invention are new and useful products and constitute a feature of the invention in their own right. Unlike products obtained using conventional resin char processing, the carbon matrix of the present products exhibits particularly high levels of adherence to the reinforcing fibres. The fibres are therefore well protected against unwanted interaction with silicon during siliconisation, and the products exhibit substantially enhanced strength and integrity compared to those of the prior art.

Whereas the carbon matrix in resin char products of the prior art predominantly comprises amorphous glassy carbon, the matrix carbon content of the present products is comparatively more ordered, generally being in an isotropic, rough laminar or smooth laminar form. This is advantageous in that it permits more even and controlled interactions with silicon during siliconisation, permitting the manufacture of more uniform and reproducible products.

Long fibre-containing products are a particularly advantageous embodiment of the invention by virtue of the strength and integrity imparted by such reinforcement. Thus according to a further feature of the invention there is provided a carbon fibre-reinforced ceramic brake or clutch disc for a motorised land vehicle, said disc consisting essentially of a network of reinforcing carbon fibres which has an average fibre length of at least 50 mm, and which is substantially completely encapsulated within a siliconised mixture of carbon in isotropic, rough laminar or smooth laminar form.

Once again it is preferred in this embodiment of the invention that the average length of the reinforcing fires is equal to or exceeds the radial distance between the inner and outer peripheries of the disc.

Preferred products of this embodiment of the invention may, for example, be characterised by relative carbon (combined matrix and reinforcing fibres):silicon carbide:free silicon contents in the range 50-65%:30-45%:1-10%, more preferably 55-60%:35-40%:2-6%, all percentages being by weight.

1-17. (canceled)

18. A method for the manufacture of a carbon fiber-reinforced ceramic brake or clutch disc for a motorized land vehicle, which method comprises preparing a carbon fiber preform having dimensions which substantially correspond to those of the brake or clutch disc, densifying the preform with carbon in a single stage chemical vapour infiltration process, and siliconizing the densified preform by reaction with molten silicon.

19. The method of claim 18, wherein the average length of the carbon fibers within the preform is at least 50 mm.

20. The method of claim 18, wherein the average length of the carbon fibers within the preform is equal to or exceeds the radial distance between the inner and outer peripheries of the brake or clutch disc.

21. The method as claimed in claim 18, wherein the preform is cut from a continuous sheet or cylinder of carbon fiber fabric.

22. The method of claim 21, wherein the continuous sheet is a non-woven felt.

23. The method of claims 18, wherein the initial preform has a density of 0.3-0.6 g/cm³.

24. The method of claim 18, wherein the densified preform has a density of 1.0-1.5 g/cm³.

25. The method of claim 18, wherein the single stage chemical vapor deposition process is carried out for a total of up to 21 days.

26. The method of claim 25, wherein the deposition process is carried out for a total of 7-14 days.

27. The method of claim 18, wherein the densified preform is machined to the dimensions of the brake or clutch disc prior to the reaction with molten silicon.

28. The method of claims 18, wherein the reaction with molten silicon is carried out by at least partially immersing the densified preform in a bath of molten silicon or by encapsulation with excess silicon in an evacuated container which is subjected to high temperature and isostatic pressure.

29. The method of claim 18, wherein the siliconized densified preform is machined to the dimensions of the brake or clutch disc.

30. A carbon fiber-reinforced ceramic brake or clutch disc, made by the process of claims 18.

31. A carbon fiber-reinforced ceramic brake or clutch disc for a motorised land vehicle, wherein the brake or clutch disc consists essentially of a network of reinforcing carbon fibers which have an average fiber length of at least 50 mm and which fibers are substantially completely encapsulated within a siliconised matrix of carbon in isotropic, rough laminar or smooth laminar form.

32. The brake or clutch disc of claim 31, wherein the average length of the carbon fibers exceeds the radial distance between the inner and outer peripheries of the brake or clutch disc.

33. The brake or clutch disc of claim 31, wherein the relative carbon:silicon carbide:free silicon contents are in the respective ranges 50-65%:30-45%:1-10% by weight.

34. The brake or clutch disc of claim 31, wherein the relative carbon:silicon carbide:free silicon contents are in the respective ranges 55-60%:35-40%:2-6% by weight.
